(19) United States
(12) Patent Application Publication
(10) Pub. No.: US 2024/0324315 A1
(43) Pub. Date: Sep. 26, 2024

(54) DISPLAY APPARATUS AND METHOD OF MANUFACTURING THE SAME

(71) Applicant: Samsung Display Co., Ltd., Yongin-si (KR)

(72) Inventors: Donghoon Lee, Yongin-si (KR); Gyungsoon Park, Yongin-si (KR); Haemin Kim, Yongin-si (KR); Youngwan Seo, Yongin-si (KR); Geunho Lee, Yongin-si (KR)

(21) Appl. No.: 18/611,595

(22) Filed: Mar. 20, 2024

(30) Foreign Application Priority Data
Mar. 24, 2023 (KR) 10-2023-0039059
Apr. 27, 2023 (KR) 10-2023-0055657

(51) Int. Cl. H10K 59/122; H10K 59/12

(52) U.S. Cl. CPC H10K 59/122; H10K 59/1201

(57) ABSTRACT

A display apparatus includes: a pixel electrode; a pixel defining layer on the pixel electrode, and having an opening exposing at least a portion of the pixel electrode; a bank layer on the pixel defining layer; an overhang layer on the bank layer; an intermediate layer on the pixel electrode; and an opposite electrode on the intermediate layer. The overhang layer includes a tip protruding toward the pixel electrode from a point where a bottom surface of the overhang layer and a side surface of the bank layer facing toward the pixel electrode meet each other, and a height from an upper surface of the pixel defining layer to an upper surface of the bank layer is different from a height from the upper surface of the pixel defining layer to a bottom surface of the tip of the overhang layer.

### CROSS-REFERENCE TO RELATED APPLICATIONS

This application claims priority to and the benefit of Korean Patent Application Nos. 10-2023-0039059, filed on Mar. 24, 2023, and 10-2023-0055657, filed on Apr. 27, 2023, in the Korean Intellectual Property Office, the entire disclosures of all of which are incorporated by reference herein.

### BACKGROUND

### 1. Field

Aspects of one or more embodiments of the present disclosure relate to a display apparatus having improved reliability, and a method of manufacturing the display apparatus.

### 2. Description of the Related Art

Recently, the uses of display apparatuses have diversified. In addition, as the thicknesses of the display apparatuses have become smaller and the weights of the display apparatuses have become lighter, the ranges of use of the display apparatuses have become more widespread.

Generally, a display apparatus includes a plurality of pixels for emitting light by receiving electrical signals to display images. A pixel of an organic light-emitting display (OLED) apparatus includes an organic light-emitting diode as a display element, and a driving circuit for controlling electrical signals applied to the display element. The driving circuit includes a thin-film transistor (TFT), a storage capacitor, and a plurality of lines. The plurality of lines provide data signals, driving voltages, common voltages, or the like to a driving circuit of each pixel.

The above information disclosed in this Background section is for enhancement of understanding of the background of the present disclosure, and therefore, it may contain information that does not constitute prior art.

### SUMMARY

In a comparative example, a display apparatus may have difficulty in implementing a high resolution, or may have poor emission efficiency due to structural and process limitations.

One or more embodiments of the present disclosure are directed to a display apparatus that displays high-quality images. However, the present disclosure is not limited to the above aspects and features.

Additional aspects and features will be set forth, in part, in the description that follows, and in part, will be apparent from the description, or may be learned by practicing one or more of the presented embodiments of the present disclosure.

According to one or more embodiments of the present disclosure, a display apparatus includes: a pixel electrode; a pixel defining layer on the pixel electrode, and having an opening exposing at least a portion of the pixel electrode; a bank layer on the pixel defining layer; an overhang layer on the bank layer; an intermediate layer on the pixel electrode; and an opposite electrode on the intermediate layer. The overhang layer includes a tip protruding toward the pixel electrode from a point where a bottom surface of the overhang layer and a side surface of the bank layer facing toward the pixel electrode meet each other, and a height from an upper surface of the pixel defining layer to an upper surface of the bank layer is different from a height from the upper surface of the pixel defining layer to a bottom surface of the tip of the overhang layer.

In an embodiment, the tip of the overhang layer may have an opening overlapping with the pixel electrode; the bank layer may have an opening overlapping with the pixel electrode; and a width of the opening of the tip may be less than a width of the opening of the bank layer.

In an embodiment, the height from the upper surface of the pixel defining layer to the bottom surface of the tip of the overhang layer may be greater than the height from the upper surface of the pixel defining layer to the upper surface of the bank layer.

In an embodiment, the opposite electrode may be electrically connected to the bank layer.

In an embodiment, the opposite electrode may be electrically connected to the overhang layer.

In an embodiment, the overhang layer may include a conductive material.

In an embodiment, the height from the upper surface of the pixel defining layer to the bottom surface of the tip of the overhang layer may be less than the height from the upper surface of the pixel defining layer to the upper surface of the bank layer.

In an embodiment, the opposite electrode may be electrically connected to the bank layer.

In an embodiment, the overhang layer may include an organic insulating material or an inorganic insulating material.

In an embodiment, the opposite electrode may be electrically connected to the overhang layer.

In an embodiment, the overhang layer may include a conductive material.

In an embodiment, the display apparatus may further include: an encapsulation layer on the overhang layer and the opposite electrode; a dummy intermediate layer on the overhang layer; and a dummy opposite electrode on the dummy intermediate layer. The dummy intermediate layer and the dummy opposite electrode may be located between the overhang layer and the encapsulation layer; the dummy intermediate layer may include the same material as a material of the intermediate layer; and the dummy opposite electrode may include the same material as a material of the opposite electrode.

According to one or more embodiments of the present disclosure, a method of manufacturing a display apparatus, includes: forming a pixel electrode on a substrate; forming a pixel defining layer having an opening exposing at least a portion of the pixel electrode; forming a preliminary bank layer on the pixel defining layer and the pixel electrode; forming a bank layer having an opening overlapping with the opening of the pixel defining layer by patterning the preliminary bank layer; forming a preliminary sacrificial layer to fill the opening of the pixel defining layer and the opening of the bank layer, and to cover the bank layer; forming a sacrificial layer by patterning the preliminary sacrificial layer; forming a preliminary overhang layer on the bank layer and the sacrificial layer; forming an overhang layer having an opening overlapping with the opening of the pixel defining layer and the opening of the bank layer by patterning the preliminary overhang layer; and removing the sacrificial layer. The forming of the overhang layer includes removing a portion of the overhang layer so that a width of the opening of the overhang layer is less than a width of the opening of the bank layer.

In an embodiment, the preliminary sacrificial layer may be formed with a material including a photo-active compound.

In an embodiment, the forming of the sacrificial layer may include removing the preliminary sacrificial layer so that a height from an upper surface of the pixel defining layer to an upper surface of the sacrificial layer may be greater than a height from the upper surface of the pixel defining layer to an upper surface of the bank layer.

In an embodiment, the method may further include: forming an intermediate layer on the pixel electrode; and forming an opposite electrode on the intermediate layer. The opposite electrode may be formed to be electrically connected to the overhang layer.

In an embodiment, the forming of the sacrificial layer may include removing the preliminary sacrificial layer so that a height from an upper surface of the pixel defining layer to an upper surface of the sacrificial layer may be less than a height from the upper surface of the pixel defining layer to an upper surface of the bank layer.

In an embodiment, the method may further include: forming an intermediate layer on the pixel electrode; and forming an opposite electrode on the intermediate layer. The opposite electrode may be formed to be electrically connected to the bank layer.

In an embodiment, the opposite electrode may be formed to be electrically connected to the overhang layer.

In an embodiment, the forming of the bank layer may include removing the preliminary bank layer by dry-etching.

The above and other aspects and features of the present disclosure will become more apparent from the following detailed description with reference to the drawings, the claims, and their equivalents.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a perspective view schematically illustrating a display apparatus according to an embodiment;

FIG. 2 is a cross-sectional view schematically illustrating a cross section taken along the line A-A′ of the display apparatus of FIG. 1;

FIG. 3 is a plan view schematically illustrating a display panel of a display apparatus according to an embodiment;

FIGS. 4 and 5 are equivalent circuit diagrams schematically illustrating a pixel of a display apparatus according to one or more embodiments;

FIGS. 6 and 7 are cross-sectional views schematically illustrating a display apparatus according to one or more embodiments;

FIGS. 8 and 9 are cross-sectional views schematically illustrating a display apparatus according to one or more embodiments;

FIGS. 10-17 are cross-sectional views sequentially illustrating some processes of a method of manufacturing a display apparatus according to an embodiment;

FIGS. 18-24 are cross-sectional views sequentially illustrating some processes of a method of manufacturing a display apparatus according to an embodiment; and

FIG. 25 is a cross-sectional view illustrating a stacked structure of a light-emitting diode according to an embodiment.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. For example, when it is described that “the component of B is directly disposed on the component of A,” this may mean that a separate adhesive layer or adhesive member is not located between the component of A and the component of B. In this case, after the component of A is formed, the component of B may be formed on a base surface provided by the component of A through a continuous process. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

As used in the present disclosure, the phrase “A and B overlap with each other” may mean, in one direction (e.g., a z axis direction), at least a portion of A and at least a portion of B overlap with each other in a plan view (e.g., an xy plan view) perpendicular to or substantially perpendicular to the one direction.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. For example, “about” may mean to include values in the range of ±30%, ±20%, ±10%, or ±5% of any stated number. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

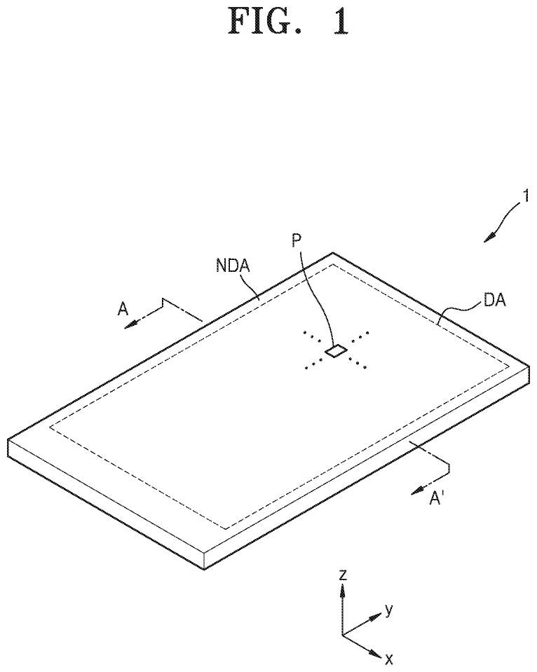

FIG. 1 is a perspective view schematically illustrating a display apparatus according to an embodiment.

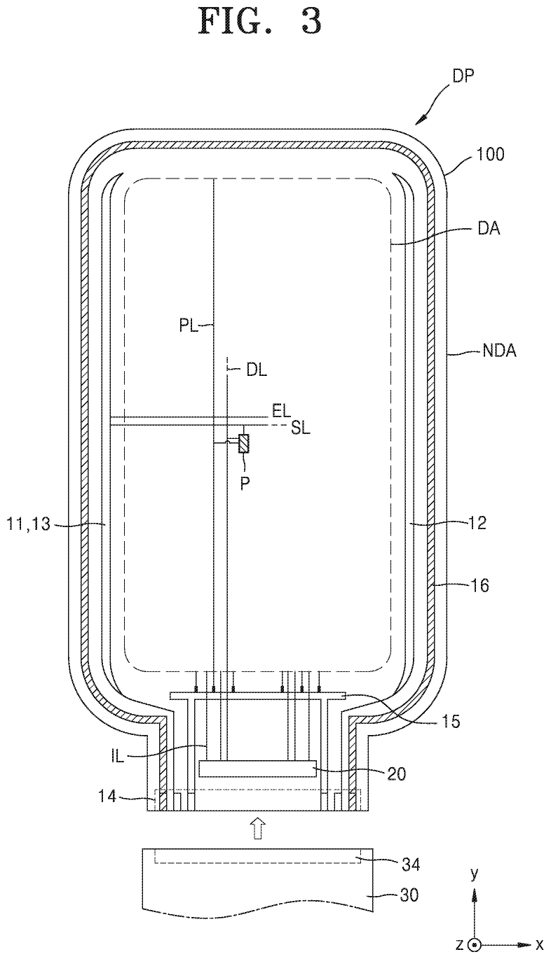

Referring to FIG. 1, a display panel of a display apparatus 1 may include a display area DA, and a non-display area NDA outside the display area DA. The display panel including the display area DA may be understood as a substrate 100 (e.g., refer to FIG. 3) of the display panel includes the display area DA. Hereinafter, for convenience, the substrate 100 is described in more detail as having the display area DA and the non-display area NDA.

The display area DA may display an image through pixels P arranged in the display area DA. The non-display area NDA is arranged outside the display area DA, and does not display an image. For example, the non-display area NDA may entirely surround (e.g., around a periphery of) the display area DA. A driver or the like for providing electrical signals or power to the display area DA may be arranged in the non-display area NDA. A pad, which is an area to which an electronic device or a printed circuit board may be electrically connected, may be arranged in the non-display area NDA.

In an embodiment, FIG. 1 shows that the display area DA has a polygonal shape (e.g., a rectangular shape) in which a length in the x direction is less than a length in the y direction, but the present disclosure is not limited thereto. In another embodiment, the display area DA may have various suitable shapes, such as an N-sided polygonal shape (where N is a natural number of 3 or more), a circular shape, or an elliptical shape. FIG. 1 shows that a corner portion of the display area DA has a shape including a vertex where the sides (e.g., straight lines) meet, but in another embodiment, the corner portion of the display area DA may be that of a polygonal shape with rounded corner portions.

Hereinafter, for convenience, a case where the display apparatus 1 is an electronic device such as a smartphone is described in more detail, but the present disclosure is not limited thereto. The display apparatus 1 may be a portable electronic device, such as a mobile phone, a smartphone, a table personal computer (PC), a mobile communication terminal, an electronic notebook, an electronic book, a portable multimedia player (PMP), a navigation device, an Ultra Mobile PC (UMPC), or the like, and may also be used in various suitable products, such as a television, a laptop computer, a monitor, an advertisement board, an Internet of things (IoT) device, or the like. Also, the display apparatus 1 according to an embodiment may be used as a wearable device, such as a smart watch, a watch phone, a glasses-type display, or a head mounted display (HMD). In addition, the display apparatus 1 according to an embodiment may be applied to a dashboard of a vehicle, a center fascia of a vehicle, or a center information display (CID) disposed on a dashboard, a rear-view mirror display replacing a side mirror of a vehicle, or a display screen disposed on a back surface of a front seat as entertainment for a passenger in the back seat of a vehicle.

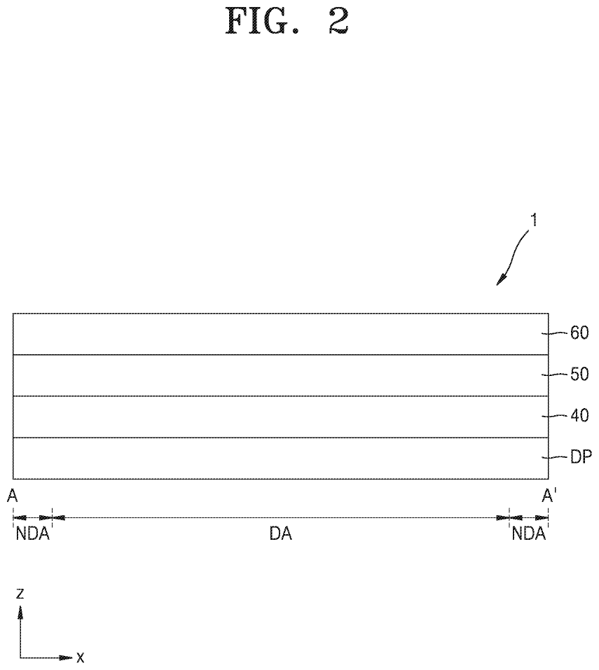

FIG. 2 is a cross-sectional view schematically illustrating a cross section taken along the line A-A′ of the display apparatus 1 of FIG. 1.

Referring to FIG. 2, the display apparatus 1 may include a display panel DP, an input sensing layer 40 disposed on the display panel DP, and an optical functional layer 50. The display panel DP, the input sensing layer 40, and the optical functional layer 50 may be covered by a window 60.

The display panel DP may display an image. The display panel DP includes the pixels arranged in the display area DA. The pixels may include a display element, and a pixel circuit connected to the display element. The display element may include an organic light-emitting diode, a quantum dot organic light-emitting diode, or the like.

The input sensing layer 40 may obtain coordinate information according to an external input, for example, such as a touch event. The input sensing layer 40 may include a sensing electrode (or a touch electrode), and a trace line connected to the sensing electrode. The input sensing layer 40 may be disposed on the display panel DP. The input sensing layer 40 may sense an external input in a mutual-cap method and/or a self-cap method.

The input sensing layer 40 may be formed directly on the display panel DP, or may be formed separately and then connected to (e.g., attached to or bonded to) the display panel DP through an adhesive layer, such as an optical clear adhesive. For example, the input sensing layer 40 may be formed continuously after a process of forming the display panel DP. In this case, the input sensing layer 40 may be understood as a portion of the display panel DP, and an adhesive layer may not be disposed between the input sensing layer 40 and the display panel DP. FIG. 2 illustrates that the input sensing layer 40 is between the display panel DP and the optical functional layer 50, but the input sensing layer 40 may be disposed above the optical functional layer 50 in another embodiment.

The optical functional layer 50 may include an anti-reflection layer. The anti-reflection layer may reduce a reflectance of light (e.g., external light) incident from the outside toward the display panel DP through the window 60. In an embodiment, the anti-reflection layer may include a black matrix and color filters. The color filters may be arranged considering the color of light emitted from each of the pixels of the display panel DP.

In another embodiment, the anti-reflection layer may include a retarder and a polarizer. The retarder may be a film type or a liquid-crystal coating type, and may include a λ/2 retarder and/or a λ/4 retarder. The polarizer may also be a film type or a liquid-crystal coating type. The film-type polarizer may include a stretch-type synthetic resin film, and the liquid-crystal-coating-type polarizer may include liquid crystals arranged in a suitable arrangement (e.g., a certain or predetermined arrangement). The retarder and the polarizer may further include a protective film. The retarder and the polarizer or the protective film may be defined as a base layer of the anti-reflection layer.

In another embodiment, the anti-reflection layer may include a destructive interference structure. The destructive interference structure may include a first reflective layer and a second reflective layer, which are arranged at (e.g., in or on) different layers from each other. First reflected light and second reflected light reflected from the first reflective layer and the second reflective layer, respectively, may destructively interfere with each other, and thus, the reflectance of the external light may be reduced.

In an embodiment, the optical functional layer 50 may be formed continuously after a process of forming the display panel DP and/or the input sensing layer 40. In this case, an adhesive layer may not be disposed between the optical functional layer 50 and the input sensing layer 40, and/or between the input sensing layer 40 and the display panel DP.

In some embodiments, a layer including an optical clear adhesive or an optical clear resin may be further disposed between the window 60 and the optical functional layer 50.

FIG. 3 is a plan view schematically illustrating a display panel of a display apparatus according to an embodiment.

The display apparatus according to an embodiment may include the display panel DP. FIG. 3 may be understood as a view (e.g., a plan view) of the substrate 100 of the display panel DP.

Referring to FIG. 3, the display panel DP includes the display area DA, and the non-display area NDA outside the display area DA. The display area DA is a portion that displays an image, and a plurality of pixels P may be arranged in the display area DA. FIG. 3 shows that the display area DA has a rectangular or substantially rectangular shape with rounded corners, but the present disclosure is not limited thereto. As described above, the display area DA may have various suitable shapes, such as an N-sided polygonal shape (where N is a natural number of 3 or more), a circular shape, or an elliptical shape.

Each of the pixels P may refer to a sub-pixel, and may include a display element, such as an organic light-emitting diode (OLED). Each pixel P may emit, for example, red, green, blue, or white light.

The non-display area NDA may be outside the display area DA. Outer circuits for driving the pixels P may be arranged in the non-display area NDA. For example, a first scan driving circuit 11, a second scan driving circuit 12, an emission control driving circuit 13, a terminal 14, a driving power supply line 15, and a common power supply line 16 may be arranged in the non-display area NDA.

The first scan driving circuit 11 may provide a scan signal to the pixel P through a scan line SL. The second scan driving circuit 12 may be arranged in parallel with the first scan driving circuit 11 with the display area DA therebetween. Some of the pixels P arranged in the display area DA may be electrically connected to the first scan driving circuit 11, and the other remaining pixels P may be connected to the second scan driving circuit 12. When desired, the second scan driving circuit 12 may be omitted, and all of the pixels P arranged in the display area DA may be electrically connected to the first scan driving circuit 11.

The emission control driving circuit 13 may be arranged on a side of the first scan driving circuit 11, and may provide an emission control signal to the pixel P through an emission control line EL. Although FIG. 3 shows that the emission control driving circuit 13 is arranged only on one side of the display area DA, the emission control driving circuit 13 may also be arranged on opposite sides of the display area DA, similarly to that of the first scan driving circuit 11 and the second scan driving circuit 12.

In an embodiment, the non-display area NDA may include a bending area extending to one side of the display area DA (e.g., in the −y direction). The bending area is bent toward a rear surface of the display area DA, so that an area of the non-display area that is visible when viewed from a front surface of the display apparatus may be reduced.

A driving chip 20 may be arranged in the non-display area NDA. The driving chip 20 may include an integrated circuit that drives the display panel DP. The integrated circuit may be a data driving integrated circuit that generates data signals, but the present disclosure is not limited thereto.

The terminal 14 may be arranged in the non-display area NDA. The terminal 14 may be exposed by not being covered by an insulating layer to be electrically connected to a printed circuit board 30. A terminal 34 of the printed circuit board 30 may be electrically connected to the terminal 14 of the display panel DP.

The printed circuit board 30 transfers signals or power of a controller to the display panel DP. A control signal generated by the controller may be transferred to each of the first scan driving circuit 11, the second scan driving circuit 12, and the emission control driving circuit 13 through the printed circuit board 30. Also, the controller may transfer a driving voltage ELVDD to the driving power supply line 15, and may provide a common voltage ELVSS to the common power supply line 16. The driving voltage ELVDD may be transferred to each pixel P through a driving voltage line PL connected to the driving power supply line 15, and the common voltage ELVSS may be transferred to an opposite electrode of each pixel P. The driving power supply line 15 may have a shape extending in one direction (e.g., the x direction) from a lower side of the display area DA. The common power supply line 16 may have a loop shape having one side open to partially surround (e.g., around a periphery of) the display area DA.

The controller may generate a data signal. The generated data signal may be transferred to an input line IL through the driving chip 20, and to the pixel P through a data line DL connected to the input line IL. For reference, a “line” may refer to a “wire”. The embodiments described in more detail below may be similar to those described above, and modification examples thereof will be described in more detail below.

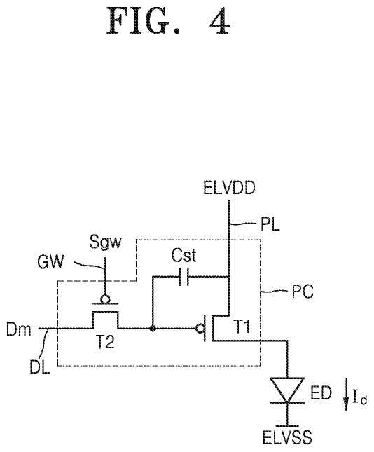

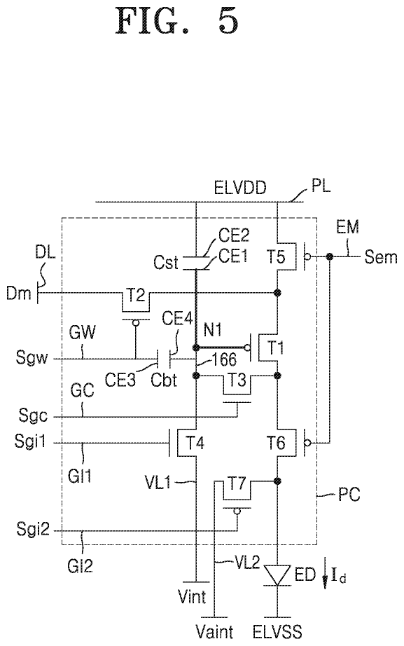

FIGS. 4 and 5 are equivalent circuit diagrams schematically illustrating a pixel of a display apparatus according to one or more embodiments.

Referring to FIG. 4, a light-emitting diode ED may be electrically connected to a pixel circuit PC. The pixel circuit PC may include a first transistor T1, a second transistor T2, and a storage capacitor Cst.

The second transistor T2 is configured to transfer, to the first transistor T1, a data signal Dm input through the data line DL according to a scan signal Sgw input through a scan line GW.

The storage capacitor Cst is connected to the second transistor T2 and the driving voltage line PL, and stores a voltage corresponding to a difference between a voltage received from the second transistor T2 and the driving voltage ELVDD supplied to the driving voltage line PL.

The first transistor T1 may be connected to the driving voltage line PL and the storage capacitor Cst, and may control a driving current 1a flowing from the driving voltage line PL to the light-emitting diode ED, in accordance with a voltage value stored in the storage capacitor Cst. An opposite electrode (e.g., a cathode) of the light-emitting diode ED may receive the common voltage ELVSS. The light-emitting diode ED may emit light having a desired brightness (e.g., a certain or predetermined brightness) according to the driving current 1d.

FIG. 4 shows that the pixel circuit PC includes two transistors and one storage capacitor, but the present disclosure is not limited thereto.

For example, referring to FIG. 5, the pixel circuit PC may include seven transistors and two capacitors.

In an embodiment, the pixel circuit PC may include first to seventh transistors T1, T2, T3, T4, T5, T6, and T7, a storage capacitor Cst, and a boost capacitor Cbt. In another embodiment, the pixel circuit PC may not include the boost capacitor Cbt.

Some of the first to seventh transistors T1, T2, T3, T4, T5, T6, and T7 may be n-channel metal-oxide-semiconductor field-effect transistors (MOSFET) (NMOS), and the other remaining transistors may be p-channel MOSFETs (PMOS). In another embodiment, the third, fourth, and seventh transistors T3, T4, and T7 may be NMOS transistors, and the other remaining transistors may be PMOS transistors.

The first to seventh transistors T1, T2, T3, T4, T5, T6, and T7, the storage capacitor Cst, and the boost capacitor Cbt may be connected to a signal line. The signal line may include the scan line GW, an emission control line EM, a compensation gate line GC, a first initialization gate line GI1, a second initialization gate line GI2, and the data line DL. The pixel circuit PC may be electrically connected to a voltage line, for example, such as the driving voltage line PL, a first initialization voltage line VL1, and a second initialization voltage line VL2.

The first transistor T1 may be a driving transistor. A first gate electrode of the first transistor T1 may be connected to the storage capacitor Cst. A first electrode of the first transistor T1 may be electrically connected to the driving voltage line PL via the fifth transistor T5, and a second electrode of the first transistor T1 may be electrically connected to a pixel electrode (e.g., an anode) of the light-emitting diode ED via the sixth transistor T6. One of the first electrode and the second electrode of the first transistor T1 may be a source electrode, and the other one may be a drain electrode. The first transistor T1 may supply the driving current 1a to the light-emitting diode ED according to a switching operation of the second transistor T2.

The second transistor T2 may be a switching transistor. A second gate electrode of the second transistor T2 may be connected to the scan line GW, a first electrode of the second transistor T2 may be connected to the data line DL, and a second electrode of the second transistor T2 may be electrically connected to the driving voltage line PL via the fifth transistor T5 and to the first electrode of the first transistor T1. One of the first electrode and the second electrode of the second transistor T2 may be a source electrode, and the other one may be a drain electrode. The second transistor T2 may be turned on according to the scan signal Sgw received through the scan line GW, and may perform a switching operation of transferring the data signal Dm delivered to the data line DL to the first electrode of the first transistor T1.

The third transistor T3 may be a compensation transistor that compensates for a threshold voltage of the first transistor T1. A third gate electrode of the third transistor T3 is connected to the compensation gate line GC. A first electrode of the third transistor T3 is connected to a lower electrode CE1 of the storage capacitor Cst and the first gate electrode of the first transistor T1 through a node connection line 166. The first electrode of the third transistor T3 may be connected to the fourth transistor T4. A second electrode of the third transistor T3 is electrically connected to the pixel electrode (e.g., the anode) of the light-emitting diode ED via the sixth transistor T6 and to the second electrode of the first transistor T1. One of the first electrode and the second electrode of the third transistor T3 may be a source electrode, and the other one may be a drain electrode.

The third transistor T3 is turned on according to a compensation signal Sgc received through the compensation gate line GC to electrically connect the first gate electrode and the second electrode (e.g., the drain electrode) of the first transistor T1 to each other, and thus, may diode-connect the first transistor T1.

The fourth transistor T4 may be a first initialization transistor that initializes the first gate electrode of the first transistor T1. A fourth gate electrode of the fourth transistor T4 is connected to the first initialization gate line GI1. A first electrode of the fourth transistor T4 is connected to the first initialization voltage line VL1. A second electrode of the fourth transistor T4 may be connected to a lower electrode CE1 of the storage capacitor Cst, the first electrode of the third transistor T3, and the first gate electrode of the first transistor T1. One of the first electrode and the second electrode of the fourth transistor T4 may be a source electrode, and the other one may be a drain electrode. The fourth transistor T4 may be turned on according to a first initialization signal Sgi1 received through the first initialization gate line GI1 to transfer a first initialization voltage Vint to the first gate electrode of the first transistor T1, and thus, may perform an initialization operation of initializing a voltage of the first gate electrode of the first transistor T1.

The fifth transistor T5 may be an operation control transistor. A fifth gate electrode of the fifth transistor T5 is connected to the emission control line EM, a first electrode of the fifth transistor T5 is connected to the driving voltage line PL, and a second electrode of the fifth transistor T5 is connected to the first electrode of the first transistor T1 and the second electrode of the second transistor T2. One of the first electrode and the second electrode of the fifth transistor T5 may be a source electrode, and the other one may be a drain electrode.

The sixth transistor T6 may be an emission control transistor. A sixth gate electrode of the sixth transistor T6 is connected to the emission control line EM, a first electrode of the sixth transistor T6 is connected to the second electrode of the first transistor T1 and the second electrode of the third transistor T3, and a second electrode of the sixth transistor T6 is electrically connected to a second electrode of the seventh transistor T7 and the pixel electrode (e.g., the anode) of the light-emitting diode ED. One of the first electrode and the second electrode of the sixth transistor T6 may be a source electrode, and the other one may be a drain electrode.

The fifth transistor T5 and the sixth transistor T6 are concurrently or substantially simultaneously turned on according to an emission control signal Sem received through the emission control line EM to allow the driving voltage ELVDD to be transferred to the light-emitting diode ED, and thus, the driving current 1a may flow through the light-emitting diode ED.

The seventh transistor T7 may be a second initialization transistor that initializes the pixel electrode (e.g., the anode) of the light-emitting diode ED. A seventh gate electrode of the seventh transistor T7 is connected to the second initialization gate line GI2. A first electrode of the seventh transistor T7 is connected to the second initialization voltage line VL2. The second electrode of the seventh transistor T7 is connected to the second electrode of the sixth transistor T6 and the pixel electrode (e.g., the anode) of the light-emitting diode ED. The seventh transistor T7 is turned on according to a second initialization signal Sgi2 received through the second initialization gate line GI2, and may transfer a second initialization voltage Vaint to the pixel electrode (e.g., the anode) of the light-emitting diode ED to initialize the pixel electrode of the light-emitting diode ED.

In an embodiment, the second initialization gate line GI2 may be a subsequent scan line. For example, the second initialization gate line GI2 connected to a seventh transistor T7 of a pixel circuit PC arranged in an i-th row (where i is a natural number) may correspond to a scan line of a pixel circuit PC arranged in the (i+1)-th row. In another embodiment, the second initialization gate line GI2 may be the emission control line EM. For example, the emission control line EM may be electrically connected to the fifth to seventh transistors T5, T6, and T7.

The storage capacitor Cst includes the lower electrode CE1 and an upper electrode CE2. The lower electrode CE1 of the storage capacitor Cst is connected to the first gate electrode of the first transistor T1, and the upper electrode CE2 of the storage capacitor Cst is connected to the driving voltage line PL. The storage capacitor Cst may store a charge corresponding to a difference between a voltage of the first gate electrode of the first transistor T1 and the driving voltage ELVDD.

The boost capacitor Cbt includes a third electrode CE3 and a fourth electrode CE4. The third electrode CE3 may be connected to the second gate electrode of the second transistor T2 and the scan line GW, and the fourth electrode CE4 may be connected to the first electrode of the third transistor T3 and the node connection line 166. When the scan signal Sgw supplied to the scan line GW is turned off (e.g., has an inactive level), the boost capacitor Cbt may increase the voltage of a first node N1. When the voltage of the first node N1 is increased, a black gradation may be more clearly expressed.

The first node N1 may be an area to which the first gate electrode of the first transistor T1, the first electrode of the third transistor T3, the second electrode of the fourth transistor T4, and the fourth electrode CE4 of the boost capacitor Cbt are connected to each other.

In an embodiment, as shown in FIG. 5, the third and fourth transistors T3 and T4 are NMOS transistors, and the first, second, and fifth to seventh transistors T1, T2, T5, T6, and T7 are PMOS transistors. The first transistor T1, which directly affects the brightness of the display apparatus that displays images, may include a semiconductor layer including polycrystalline silicon having high reliability, thereby, implementing a display apparatus having high resolution.

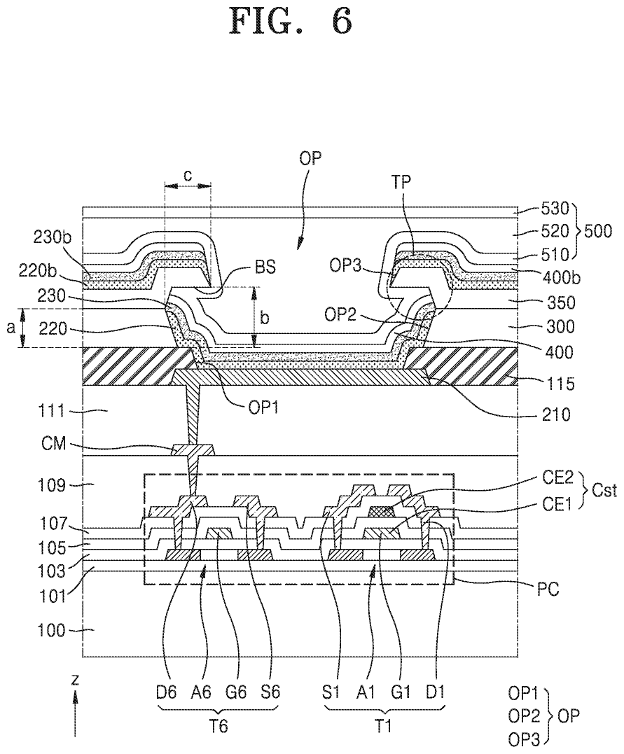

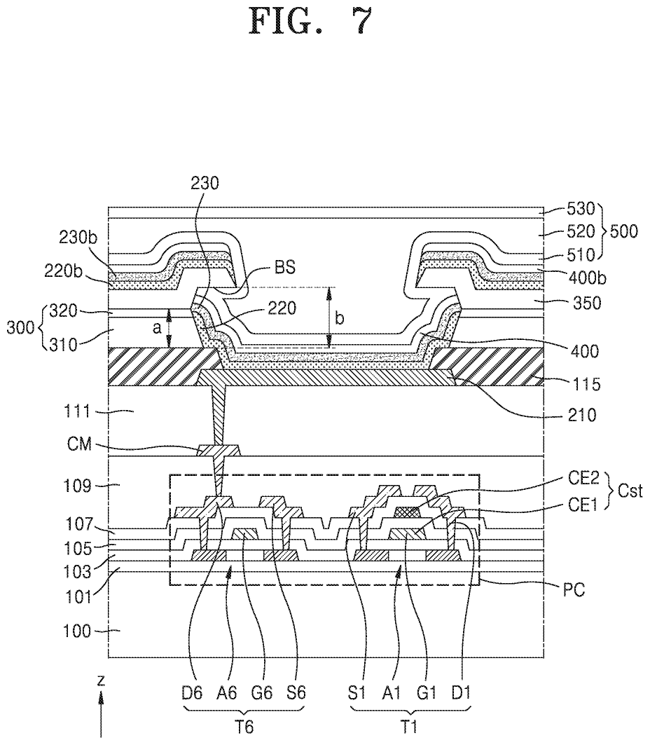

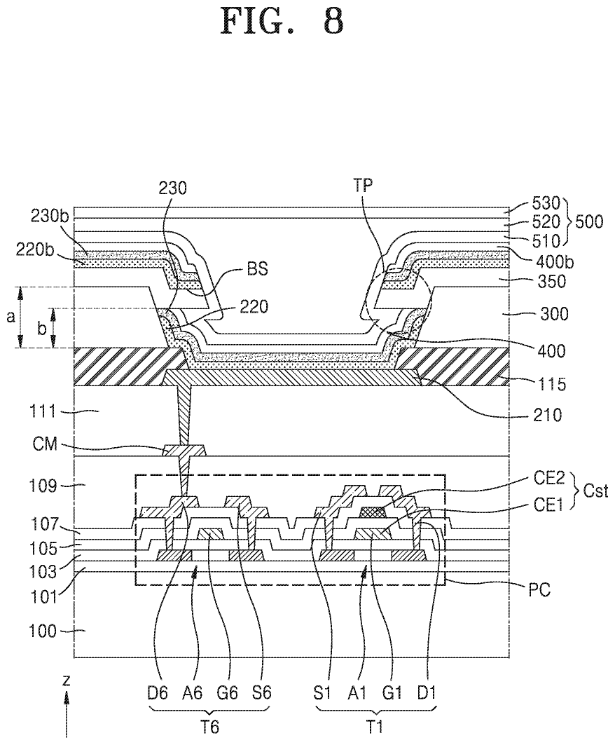

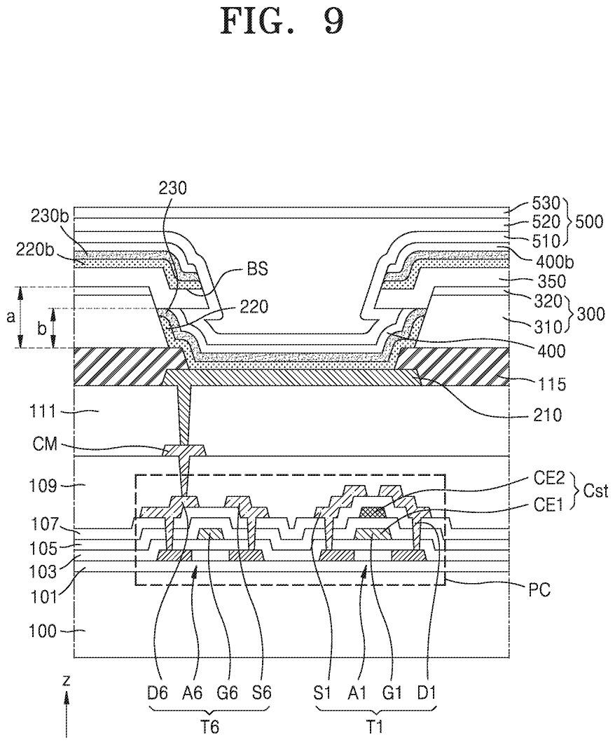

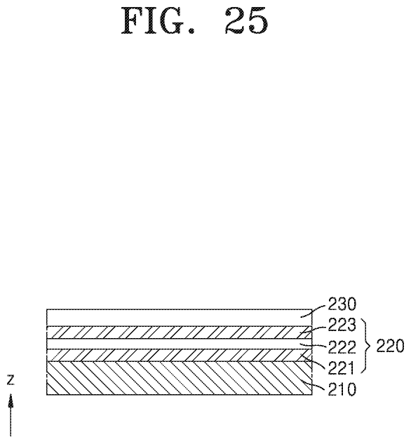

FIGS. 6 and 7 are cross-sectional views schematically illustrating a display apparatus according to one or more embodiments. FIGS. 8 and 9 are cross-sectional views schematically illustrating a display apparatus according to one or more embodiments. FIG. 25 is a cross-sectional view illustrating a stacked structure of a light-emitting diode according to an embodiment.

Referring to FIGS. 6 to 9, the pixel circuit PC may be disposed on the substrate 100. The substrate 100 may include a glass material or a polymer resin. The substrate 100 may include a structure in which a base layer including a polymer resin and a barrier layer are stacked.

The polymer resin may include (e.g., may be) polyethersulfone, polyacrylate, polyetherimide, polyethylene naphthalate, polyethylene terephthalate, polyphenylene sulfide, polyarylate, polyimide, polycarbonate, cellulose triacetate, or cellulose acetate propionate.

The barrier layer may include an inorganic material, such as silicon nitride (SiNₓ) and/or silicon oxide (SiOₓ).

A buffer layer 101 may be disposed on the substrate 100. The buffer layer 101 may prevent or substantially prevent impurities from penetrating into a semiconductor layer of a transistor. The buffer layer 101 may include an inorganic insulating material, such as silicon nitride, silicon oxynitride, and/or silicon oxide, and may include a single layer or multi-layers, each including one or more of the inorganic insulating materials described above.

The pixel circuit PC may be disposed on the buffer layer 101. The pixel circuit PC may include a plurality of transistors and a storage capacitor, as described above with reference to FIG. 4 or FIG. 5. For convenience of illustration, FIGS. 6 to 9 show parts of the first transistor T1, the sixth transistor T6, and the storage capacitor Cst of the pixel circuit PC.

The first transistor T1 may include a first semiconductor layer A1 on the buffer layer 101, and a first gate electrode G1 overlapping with a channel area of the first semiconductor layer A1. The first semiconductor layer A1 may include a silicon-based semiconductor material, for example, such as polysilicon. The first semiconductor layer A1 may include the channel area, and a first area and a second area arranged on opposite sides of the channel area, respectively. Each of the first area and the second area is an area including a higher concentration of impurities than that of the channel area. Any one of the first area and the second area may be a source area, and the other one may correspond to a drain area.

The sixth transistor T6 may include a sixth semiconductor layer A6 on the buffer layer 101, and a sixth gate electrode G6 overlapping with a channel area of the sixth semiconductor layer A6. The sixth semiconductor layer A6 may include a silicon-based semiconductor material, for example, such as polysilicon. The sixth semiconductor layer A6 may include the channel area, and a first area and a second area arranged on opposite sides of the channel area, respectively. Each of the first area and the second area is an area including a higher concentration of impurities than that of the channel area. Any one of the first area and the second area may be a source area, and the other one may correspond to a drain area.

The first gate electrode G1 and the sixth gate electrode G6 may each include a conductive material, such as molybdenum (Mo), aluminum (Al), copper (Cu), titanium (Ti), or the like, and may include a single layer or multi-layers, each including one or more of the above materials. A first gate insulating layer 103 for electrical insulation between the first semiconductor layer A1 and the sixth semiconductor layer A6 may be disposed below (e.g., underneath) the first gate electrode G1 and the sixth gate electrode G6. The first gate insulating layer 103 may include an inorganic insulating material, such as silicon nitride, silicon oxynitride, and/or silicon oxide, and may include a single layer or multi-layers, each including one or more of the inorganic insulating materials described above.

The storage capacitor Cst may include the lower electrode CE1 and the upper electrode CE2, which overlap with each other. In an embodiment, the lower electrode CE1 of the storage capacitor Cst may include the first gate electrode G1. In other words, the first gate electrode G1 may include the lower electrode CE1 of the storage capacitor Cst. For example, the first gate electrode G1 and the lower electrode CE1 of the storage capacitor Cst may be an integral body.

A first interlayer insulating layer 105 may be between the lower electrode CE1 of the storage capacitor Cst and the upper electrode CE2. The first interlayer insulating layer 105 may include an inorganic insulating material, such as silicon oxide, silicon nitride, and/or silicon oxynitride, and may include a single-layer or a multi-layered structure, each including one or more of the above inorganic insulating materials.

The upper electrode CE2 of the storage capacitor Cst may include a low-resistance conductive material, such as Mo, Al, Cu, and/or Ti, and may include a single-layer or a multi-layered structure, each including one or more of the above materials.

A second interlayer insulating layer 107 may be disposed on the storage capacitor Cst. The second interlayer insulating layer 107 may include an inorganic insulating material, such as silicon oxide, silicon nitride, and/or silicon oxynitride, and may include a single-layer or a multi-layered structure, each including one or more of the above inorganic insulating materials.

A source electrode S1 and/or a drain electrode D1 electrically connected to the first semiconductor layer A1 of the first transistor T1 may be disposed on the second interlayer insulating layer 107. A source electrode S6 and/or a drain electrode D6 electrically connected to the sixth semiconductor layer A6 of the sixth transistor T6 may be disposed on the second interlayer insulating layer 107. The source electrodes S1 and S6 and/or the drain electrodes D1 and D6 may be at (e.g., in or on) the same layer as that of the data line DL, and may include the same material as that of the data line DL. The source electrodes S1 and S6 and/or the drain electrodes D1 and D6 may each include a conductive material including Mo, Al, Cu, and/or the like, and may include a single layer or multi-layers, each including one or more of the above materials. In an embodiment, the source electrodes S1 and S6, the drain electrodes D1 and D6, and the data line DL may each include a multi-layered structure of Ti/Al/Ti.

A first planarization layer 109 may be disposed on the pixel circuit PC. The first planarization layer 109 may include a general commercial polymer, such as poly(methyl methacrylate) (PMMA) or polystyrene (PS), a polymer derivative having a phenol group, and/or an organic insulating material, such as an acrylic polymer, an imide polymer, an aryl ether polymer, an amide polymer, a fluorine polymer, a p-xylene polymer, a vinyl alcohol polymer, and/or a suitable mixture thereof.

A connection metal CM may be disposed on the first planarization layer 109. The connection metal CM may include Mo, Al, Cu, and/or Ti, and may have a single layer or multi-layers, each including one or more of the above materials.

A second planarization layer 111 may be disposed between the connection metal CM and a pixel electrode 210. The second planarization layer 111 may include a general commercial polymer, such as PMMA or PS, a polymer derivative having a phenol group, and/or an organic insulating material, such as an acrylic polymer, an imide polymer, an aryl ether polymer, an amide polymer, a fluorine polymer, a p-xylene polymer, a vinyl alcohol polymer, and/or a suitable mixture thereof. In an embodiment, the first planarization layer 109 and the second planarization layer 111 may each include polyimide.

The pixel electrode 210 may be formed on the second planarization layer 111. The pixel electrode 210 may be formed to be a (semi)transparent electrode or a reflective electrode. When the pixel electrode 210 is formed as a (semi) transparent electrode, the pixel electrode 210 may include, for example, indium tin oxide (ITO), indium zinc oxide (IZO), zinc oxide (ZnO), indium oxide (In₂O₃), indium gallium oxide (IGO), or aluminum zinc oxide (AZO). When the pixel electrode 210 is formed as a reflective electrode, a reflective film including silver (Ag), Mg, Al, platinum (Pt), palladium (Pd), gold (Au), nickel (Ni), neodymium (Nd), iridium (Ir), chromium (Cr), or a suitable compound thereof may be formed, and a film including ITO, IZO, ZnO, or In₂O₃ may be formed on the reflective film. In an embodiment, the pixel electrode 210 may have a structure in which an ITO layer, an Ag layer, and an ITO layer are sequentially stacked. The pixel electrode 210 may be electrically connected to the connection metal CM through a contact hole of (e.g., penetrating) the second planarization layer 111.

According to one or more embodiments described above with reference to FIGS. 6 to 9, the pixel circuit PC and the pixel electrode 210 are electrically connected to each other through the connection metal CM, but the present disclosure is not limited thereto. According to another embodiment, the connection metal CM may be omitted, and one planarization layer may be between the pixel circuit PC and the pixel electrode 210. According to another embodiment, three or more planarization layers may be between the pixel circuit PC and the pixel electrode 210, and the pixel circuit PC and the pixel electrode 210 may be electrically connected to each other through a plurality of connection metals.

A pixel defining layer 115 may be disposed on the second planarization layer 111. The pixel electrode 210 may be between the second planarization layer 111 and the pixel defining layer 115. Accordingly, it may be said that the pixel defining layer 115 is disposed on the pixel electrode 210. The pixel defining layer 115 may have an opening through which at least a portion of the pixel electrode 210 is exposed. In an embodiment, the pixel defining layer 115 may define a pixel by having an opening corresponding to each sub-pixel, or in other words, a first sub-opening OP1 through which at least a central portion of the pixel electrode 210 is exposed. The pixel defining layer 115 may cover a side surface of the pixel electrode 210. In other words, when viewed in a direction (e.g., the z axis direction) perpendicular to or substantially perpendicular to the substrate 100 (e.g., in a plan view), the pixel defining layer 115 may overlap with an edge of the pixel electrode 210.

The pixel defining layer 115 may include an organic insulating material and/or an inorganic insulating material. In an embodiment, the pixel defining layer 115 may include an inorganic insulating material, such as silicon oxide, silicon nitride, and/or silicon oxynitride. When the pixel defining layer 115 includes an inorganic insulating material, a distance between each of the sub-pixels may be formed shorter. In an embodiment, the pixel defining layer 115 may include one or more organic insulating materials selected from the group consisting of polyimide, polyamide, acrylic resin, benzocyclobutene (BCB), and phenol resin. In an embodiment, the pixel defining layer 115 may include a multi-layered structure including one or more of the above-described inorganic insulating materials and one or more of the above-described organic insulating materials.

In some embodiments, a remaining pixel protective layer may be disposed between the pixel electrode 210 and the pixel defining layer 115. The remaining pixel protective layer may be a portion remaining after a pixel protective layer that protects an upper surface of the pixel electrode 210 is removed during a manufacturing process of the display apparatus. When viewed in a direction (e.g., the z axis direction) perpendicular to or substantially perpendicular to the substrate 100 (e.g., in a plan view), the remaining pixel protective layer may be in an area where the pixel electrode 210 and the pixel defining layer 115 overlap with each other. For example, the remaining pixel protective layer may be positioned along an edge of the pixel electrode 210 to expose the central portion of the pixel electrode 210. The remaining pixel protective layer may include a conductive oxide, such as ITO, IZO, indium gallium zinc oxide (IGZO), indium tin zinc oxide (ITZO), ZnO, AZO, gallium doped zinc oxide (GZO), zinc tin oxide (ZTO), gallium tin oxide (GTO), fluorine doped tin oxide (FTO), or the like.

A bank layer 300 may be disposed on the pixel defining layer 115. The bank layer 300 may include a second sub-opening OP2 exposing the central portion of the pixel electrode 210. The second sub-opening OP2 of the bank layer 300 may overlap with the first sub-opening OP1 of the pixel defining layer 115.

Still referring to FIGS. 6 to 9, in an embodiment, a side surface of the bank layer 300 may have an inclined surface tapered in a forward direction. For example, a width of an upper portion of the second sub-opening OP2 of the bank layer 300 may be greater than a width of a lower portion of the second sub-opening OP2. However, the present disclosure is not limited thereto. In an embodiment, the side surface of the bank layer 300 may be perpendicular to or substantially perpendicular to the substrate 100. In an embodiment, the side surface of the bank layer 300 may have an inclined surface tapered in a reverse direction. In other words, the width of the upper portion of the second sub-opening OP2 of the bank layer 300 may be less than the width of the lower portion of the second sub-opening OP2.

The bank layer 300 may include a conductive material. For example, the bank layer 300 may include a conductive material including Mo, Al, Cu, Ti, or the like, and may be multi-layers or a single layer, each including one or more of the above materials. In an embodiment, as illustrated in FIG. 6, the bank layer 300 may include a single layer including one of the above materials. In an embodiment, as illustrated in FIG. 7, the bank layer 300 may include a first sub-bank layer 310 and a second sub-bank layer 320. The first sub-bank layer 310 and the second sub-bank layer 320 may include different metals from each other. In an embodiment, the first sub-bank layer 310 may be a layer including Al, and the second sub-bank layer 320 may be a layer including Ti. A thickness of the first sub-bank layer 310 may be formed to be greater than a thickness of the second sub-bank layer 320. In other words, the thickness of the second sub-bank layer 320 may be formed to be less than the thickness of the first sub-bank layer 310. In an embodiment, the thickness of the first sub-bank layer 310 may be greater than about five times of the thickness of the second sub-bank layer 320.

The bank layer 300 and the pixel defining layer 115 may extend from the display area DA to the non-display area NDA to be electrically connected to the common power supply line 16 (e.g., refer to FIG. 3). In this case, the pixel defining layer 115 may have an opening portion exposing a portion of an upper surface of the common power supply line 16 by overlapping with the common power supply line 16. The bank layer 300 may be in direct contact with the common power supply line 16 through the opening portion of the pixel defining layer 115, or may be electrically connected to the common power supply line 16 through a conductive layer between the bank layer 300 and the common power supply line 16. In other words, the bank layer 300 may be electrically connected to the common power supply line 16. In an embodiment, the first sub-bank layer 310 may be in direct contact with the common power supply line 16 through the opening portion of the pixel defining layer 115, or may be electrically connected to the common power supply line 16 through a conductive layer between the first sub-bank layer 310 and the common power supply line 16. In order words, the first sub-bank layer 310 may be electrically connected to the common power supply line 16.

An overhang layer 350 may be disposed on the bank layer 300. The overhang layer 350 may include a third sub-opening OP3 exposing the central portion of the pixel electrode 210. The third sub-opening OP3 of the overhang layer 350 may overlap with the pixel electrode 210, the first sub-opening OP1 of the pixel defining layer 115, and the second sub-opening OP2 of the bank layer 300. A width of the third sub-opening OP3 may be less than a width of the second sub-opening OP2. Accordingly, the overhang layer 350 may have tip TP protruding toward the central portion of the pixel electrode 210. In order words, the tip TP, which is a portion of the overhang layer 350, may protrude toward the pixel electrode 210 from a point where a bottom surface of the overhang layer 350 and a side surface of the bank layer 300 facing toward the pixel electrode 210 meet each other. When viewed from a direction (e.g., the z axis direction) perpendicular to or substantially perpendicular to the substrate 100, the tip TP of the overhang layer 350 may have a loop shape completely surrounding (e.g., around a periphery of) the pixel electrode 210. Accordingly, it may be said that the tip TP of the overhang layer 350 includes the third sub-opening OP3 overlapping with the pixel electrode 210. A length c of the tip TP may be about 5 μm or less. In an embodiment, the length c of the tip TP may be about 0.3 μm to about 1 μm, or about 0.3 μm to about 0.7 μm. The “length c of the tip TP” may be a distance from a point where the bottom surface of the overhang layer 350 and the side surface of the bank layer 300 facing toward the pixel electrode 210 meet each other to an end portion of the tip TP closest to the central portion of the pixel electrode 210, when viewed from a direction (e.g., the z axis direction) perpendicular to or substantially perpendicular to the substrate 100.

The overhang layer 350 may include a conductive material, such as Mo, Al, Cu, and/or Ti. The overhang layer 350 may include an organic insulating material, such as acrylic, BCB, polyimide, or HMDSO. The overhang layer 350 may include an inorganic insulating material, such as silicon oxide, silicon nitride, and/or silicon oxynitride. The overhang layer 350 may include a single-layer or a multi-layered structure, each including one or more of the above materials. In an embodiment, the overhang layer 350 may include Ti.

Referring to FIGS. 6 and 7, the tip TP of the overhang layer 350 according to an embodiment may be formed to be higher (e.g., in the z-axis direction) than the bottom surface of the overhang layer 350 where the overhang layer 350 is in contact with the bank layer 300. In other words, a height b from the upper surface of the pixel defining layer 115 to a bottom surface BS of the tip TP of the overhang layer 350 may be greater than a height a from the upper surface of the pixel defining layer 115 to an upper surface of the bank layer 300. In an embodiment, the height a may be about 0.2 μm to about 0.4 μm, and the height b may be about 0.5 μm to about 0.7 μm. In an embodiment, the height a may be about 0.3 μm, and the height b may be about 0.6 μm. However, the present disclosure is not limited thereto. The height a and the height b may be heights that are appropriately selected by those skilled in the art according to process conditions. For example, when an opposite electrode 230 does not sufficiently contact the bank layer 300, and an intermediate layer 220 entirely covers the side surface of the bank layer 300 due to a thickness of the bank layer 300 being too small, the height a from the upper surface of the pixel defining layer 115 to the upper surface of the bank layer 300 may be formed to be greater than the height b from the upper surface of the pixel defining layer 115 to the bottom surface BS of the tip TP of the overhang layer 350. In this case, even when the opposite electrode 230 does not sufficiently contact the bank layer 300, the opposite electrode 230 may receive a common power supply through contact with the overhang layer 350. As such, the overhang layer 350 may include a conductive material, such as Mo, Al, Cu, and/or Ti.

Referring to FIGS. 8 and 9, the tip TP of the overhang layer 350 according to an embodiment may be formed to be lower (e.g., in the z-axis direction) than the bottom surface of the overhang layer 350 where the overhang layer 350 is in contact with the bank layer 300. In other words, the height b from the upper surface of the pixel defining layer 115 to the bottom surface BS of the tip TP of the overhang layer 350 may be less than the height a from the upper surface of the pixel defining layer 115 to the upper surface of the bank layer 300. In an embodiment, the height a may be about 0.6 μm to about 1.0 μm, and the height b may be about 0.5 μm to about 0.7 μm. In an embodiment, the height a may be about 0.9 μm, and the height b may be about 0.6 μm. However, the present disclosure is not limited thereto. The height a and the height b may be heights that are appropriately selected by those skilled in the art according to process conditions. When the light emission efficiency of a display apparatus is poor or the viewing angle of the display apparatus is decreased because the thickness of the bank layer 300 is too large, the height b from the upper surface of the pixel defining layer 115 to the bottom surface BS of the tip TP of the overhang layer 350 may be formed to be less than the height a from the upper surface of the pixel defining layer 115 to the upper surface of the bank layer 300. In this case, because the tip TP of the overhang layer 350 is formed to be low, the light emission efficiency and viewing angle of the display apparatus may be improved.

The intermediate layer 220 may be disposed on the pixel electrode 210, and the opposite electrode 230 may be disposed on the intermediate layer 220. The intermediate layer 220 and the opposite electrode 230 may overlap with the pixel electrode 210. The pixel electrode 210, the intermediate layer 220, and the opposite electrode 230 may overlap with each other to form the light-emitting diode ED.

As shown in FIG. 25, the intermediate layer 220 may include an emission layer 222. The intermediate layer 220 may include a common layer between the pixel electrode 210 and the emission layer 222 and/or between the emission layer 222 and the opposite electrode 230. Hereinafter, the common layer between the pixel electrode 210 and the emission layer 222 may be referred to as a first common layer 221, and the common layer between the emission layer 222 and the opposite electrode 230 may be referred to as a second common layer 223.

The emission layer 222 may include a polymer organic material or a low-molecular-weight organic material, which emits light of a desired color (e.g., a certain or predetermined color, such as red, green, or blue). In another embodiment, the emission layer 222 may include an inorganic material or quantum dots.

The first common layer 221 may include a hole transport layer (HTL) and/or a hole injection layer (HIL). The second common layer 223 may include an electron transport layer (ETL) and/or an electron injection layer (EIL). The first common layer 221 and the second common layer 223 may each include an organic material.

The intermediate layer 220 may have a single-stacked structure including a single emission layer, or may have a tandem structure, which is a multi-stacked structure including a plurality of emission layers. When the intermediate layer 220 has a tandem structure, a charge generation layer (CGL) may be arranged between adjacent stacks of the multi-stacked structure.

The opposite electrode 230 may include a conductive material having a low work function. For example, the opposite electrode 230 may include a (semi)transparent layer including Ag, Mg, Al, Pt, Pd, Au, Ni, Nd, Ir, Cr, lithium (Li), Ca, a suitable alloy thereof, or the like. As another example, the opposite electrode 230 may further include a layer, such as ITO, IZO, ZnO, or In₂O₃, above the (semi)transparent layer including one or more of the materials described above.

Referring back to FIGS. 6 to 9, the intermediate layer 220 may be electrically connected to the pixel electrode 210. In an embodiment, the intermediate layer 220 may be in contact with the pixel electrode 210. The opposite electrode 230 may be disposed on the intermediate layer 220.

Referring to FIGS. 6 and 7, the opposite electrode 230 may be electrically connected to the overhang layer 350. In an embodiment, an edge or an outer portion (e.g., a peripheral portion) of the intermediate layer 220 may cover up to an upper portion of the side surface of the bank layer 300. In an embodiment, a portion (e.g., only a portion) of the edge or the outer portion (e.g., the peripheral portion) of the opposite electrode 230 may be in contact with the side surface of the bank layer 300. In an embodiment, the edge or the outer portion (e.g., the peripheral portion) of the opposite electrode 230 may not be in contact with the bank layer 300. In this case, the opposite electrode 230 may be in contact with the overhang layer 350, and may receive a common power supply through the overhang layer 350. In this case, the overhang layer 350 may include a conductive material, such as Mo, Al, Cu, and/or Ti. As used herein, “the edge or the outer portion (e.g., the peripheral portion) of the opposite electrode 230” refers to a portion of the opposite electrode 230, the portion including the edge of the opposite electrode 230. This also similarly applies to the intermediate layer 220.

Referring to FIGS. 8 and 9, the opposite electrode 230 may be electrically connected to the bank layer 300. In an embodiment, the edge or the outer portion (e.g., the peripheral portion) of the opposite electrode 230 may cover an edge or an outer portion (e.g., a peripheral portion) of the intermediate layer 220, and may be in contact with the side surface of the bank layer 300. In this case, the opposite electrode 230 may receive a common power supply through the bank layer 300. In an embodiment, the opposite electrode 230 may be electrically connected to the overhang layer 350. In other words, the edge or the outer portion (e.g., the peripheral portion) of the opposite electrode 230 may be in contact with the overhang layer 350. The opposite electrode 230 may receive a common power supply through the bank layer 300 and the overhang layer 350. In this case, the overhang layer 350 may include a conductive material, such as Mo, Al, Cu, and/or Ti. In an embodiment, the edge or the outer portion (e.g., the peripheral portion) of the opposite electrode 230 may cover the edge or the outer portion (e.g., the peripheral portion) of the intermediate layer 220, and be in contact with the side surface of the bank layer 300, but may not be in contact with the overhang layer 350. In this case, the overhang layer 350 may not include a conductive material.

A dummy intermediate layer 220b may be disposed on the overhang layer 350, and a dummy opposite electrode 230b may be disposed on the dummy intermediate layer 220b. The intermediate layer 220 and the dummy intermediate layer 220b may be separated and spaced apart from each other, and the opposite electrode 230 and the dummy opposite electrode 230b may be separated and spaced apart from each other. The intermediate layer 220 and the dummy intermediate layer 220b may include the same material as each other and/or the same number of sub-layers (e.g., a first common layer, an emission layer, and a second common layer) as each other. The opposite electrode 230 and the dummy opposite electrode 230b may include the same material as each other.

A capping layer 400 and an encapsulation layer 500 may be disposed on the light-emitting diode ED.

The capping layer 400 may be disposed on the opposite electrode 230. In an embodiment, the capping layer 400 may be between the opposite electrode 230 and a first inorganic encapsulation layer 510 to be described in more detail below.

A dummy capping layer 400b may be further disposed on the dummy opposite electrode 230b. The capping layer 400 and the dummy capping layer 400b may be separated and spaced apart from each other. The capping layer 400 and the dummy capping layer 400b may include the same material as each other. In an embodiment, the capping layer 400 may be omitted as needed or desired.

The capping layer 400 may improve the external light emission efficiency of the light-emitting diode ED by a principle of constructive interference, while protecting the opposite electrode 230 at the same time. The capping layer 400 may be formed by stacking layers having different refractive indices from each other. For example, a refractive index of the capping layer 400 may be about 1.7 to about 1.9.

The capping layer 400 may be an organic capping layer including an organic material, an inorganic capping layer including an inorganic material, or a composite capping layer including an organic material and an inorganic material.

The encapsulation layer 500 may include at least one inorganic encapsulation layer, and at least one organic encapsulation layer. FIGS. 6 to 9 show that the encapsulation layer 500 includes the first inorganic encapsulation layer 510, an organic encapsulation layer 520 on the first inorganic encapsulation layer 510, and a second inorganic encapsulation layer 530 on the organic encapsulation layer 520, but the present disclosure is not limited thereto.

The first inorganic encapsulation layer 510 may include a transparent inorganic material having a low refractive index, and may be deposited by using a suitable method such as a chemical vapor deposition method. The first inorganic encapsulation layer 510 may include silicon oxide, magnesium fluoride, or the like, and may include a single layer or multi-layers, each including one or more of the materials described above. The refractive index of the first inorganic encapsulation layer 510 may be about 1.3 to about 1.6.

The first inorganic encapsulation layer 510 may have relatively excellent step coverage. Accordingly, the first inorganic encapsulation layer 510 may cover at least a portion of an inner surface of an opening OP of an undercut structure. In an embodiment, the first inorganic encapsulation layer 510 may be continuously formed to overlap with (or to cover) upper and side surfaces of the dummy capping layer 400b, a side surface of the dummy opposite electrode 230b, a side surface of the dummy intermediate layer 220b, side and bottom surfaces of the overhang layer 350, and an upper surface of the capping layer 400. In an embodiment in which the capping layer 400 is omitted, the first inorganic encapsulation layer 510 may be continuously formed to overlap with (or to cover) upper and side surfaces of the dummy opposite electrode 230b, the side surface of the dummy intermediate layer 220b, the side and bottom surfaces of the overhang layer 350, and the upper surface of the opposite electrode 230. The first inorganic encapsulation layer 510 may reduce or block a path through which impurities, such as moisture and/or air, penetrate.

The organic encapsulation layer 520 may be formed on the first inorganic encapsulation layer 510. The organic encapsulation layer 520 may provide a flat or substantially flat base surface for the components disposed on an upper portion of the organic encapsulation layer 520 by filling at least a portion or an entirety of the opening OP.

The organic encapsulation layer 520 may include a transparent organic material having a high refractive index. The transparent organic material having a high refractive index may be an acryl-based and/or siloxane-based organic material having a refractive index of about 1.6 or greater. In an embodiment, the organic encapsulation layer 520 may include acrylate. In an embodiment, the organic encapsulation layer 520 may include a single-layer or a multi-layered structure, each including one or more of the above materials.

The organic encapsulation layer 520 may include high-refractive-index particles dispersed in the transparent organic material. For example, the high-refractive-index particles may include zirconium oxide, zinc oxide, titanium oxide, niobium oxide, tantalum oxide, tin oxide, nickel oxide, silicon nitride, indium nitride, gallium nitride, or the like.

The organic encapsulation layer 520 may have a greater refractive index than that of the first inorganic encapsulation layer 510. For example, the refractive index of the organic encapsulation layer 520 may be about 1.6 to about 2.5. In an embodiment, the organic encapsulation layer 520 may have a multi-layered structure including a plurality of layers having different refractive indices from one another.

In an embodiment, the organic encapsulation layer 520 may be entirely formed on the substrate 100. In this case, the organic encapsulation layer 520 filling a plurality of openings OP may be integrally formed, and may provide a flatter base surface.

The second inorganic encapsulation layer 530 may be disposed on the organic encapsulation layer 520. The second inorganic encapsulation layer 530 may include at least one inorganic material from among aluminum oxide, titanium oxide, tantalum oxide, hafnium oxide, zinc oxide, silicon oxide, silicon nitride, and silicon oxynitride. The second inorganic encapsulation layer 530 may include a single layer or multi-layers including one or more of the above materials.

In an embodiment, the second inorganic encapsulation layer 530 may have a refractive index less than that of the organic encapsulation layer 520. For example, the refractive index of the second inorganic encapsulation layer 530 may be about 1.3 to about 1.6.

The second inorganic encapsulation layer 530 may prevent or substantially prevent damage to the organic encapsulation layer 520 in a subsequent process, and may provide a flat or substantially flat base surface for the components on the second inorganic encapsulation layer 530.

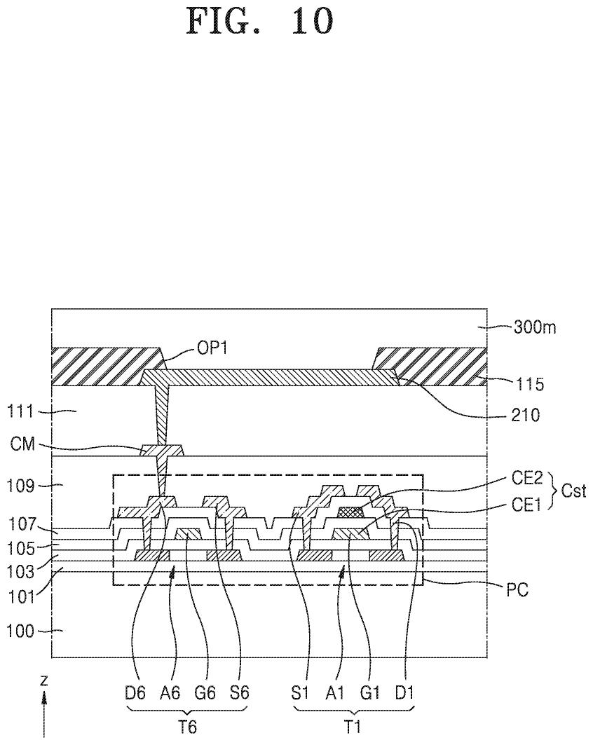

FIGS. 10 through 17 are cross-sectional views sequentially illustrating some processes of a method of manufacturing a display apparatus according to an embodiment.

Referring to FIG. 10, the pixel circuit PC may be formed on the substrate 100. For convenience of illustration, FIG. 10 shows the first transistor T1, the sixth transistor T6, and the storage capacitor Cst of the pixel circuit PC described above with reference to FIG. 6.

The substrate 100 may include a glass material or a polymer resin. The buffer layer 101, the first gate insulating layer 103, the first interlayer insulating layer 105, and the second interlayer insulating layer 107 may be formed on the substrate 100. The first planarization layer 109 and the second planarization layer 111, which cover the pixel circuit PC, may be formed on the second interlayer insulating layer 107. The second planarization layer 111 may be formed to have a flat or substantially flat upper surface. The pixel electrode 210 that is electrically connected to the pixel circuit PC may be formed on the second planarization layer 111. The pixel electrode 210 may be formed to be electrically connected to the pixel circuit PC through the connection metal CM. In an embodiment, the pixel electrode 210 may be formed to be in direct contact with the pixel circuit PC.

The pixel defining layer 115 may be formed on the second planarization layer 111 to have an opening exposing at least a portion of the pixel electrode 210. In an embodiment, the pixel defining layer 115 may be formed on the second planarization layer 111 to have the first sub-opening OP1 exposing the central portion of the pixel electrode 210. In other words, the pixel defining layer 115 may be formed to cover a side surface of the pixel electrode 210.

In some embodiments, a pixel protective layer may be further formed on the pixel electrode 210. The pixel protective layer may include a conductive oxide, such as ITO, IZO, IGZO, ITZO, ZnO, AZO, GZO, ZTO, GTO, FTO, or the like. The pixel protective layer may protect an upper surface of the pixel electrode 210 during a subsequent (e.g., a future) manufacturing process.

A preliminary bank layer 300m may be formed on the pixel defining layer 115 and the pixel electrode 210. The preliminary bank layer 300m may be formed by a suitable method such as sputtering. However, the present disclosure is not limited thereto. The preliminary bank layer 300m may be formed by a suitable method deemed appropriate by those skilled in the art.

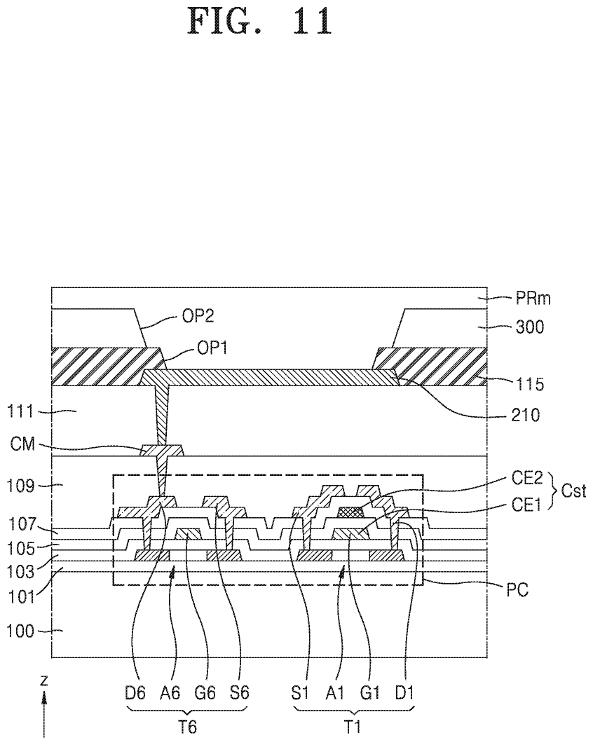

Referring to FIG. 11, the bank layer 300 may be formed by patterning the preliminary bank layer 300m to have the second sub-opening OP2 exposing an entirety or a portion of an upper portion of the pixel electrode 210 and a portion of an upper portion of the pixel defining layer 115. In order words, the bank layer 300 may be formed to have the second sub-opening OP2 overlapping with the pixel electrode 210 and the first sub-opening OP1 by patterning the preliminary bank layer 300m.

In an embodiment, the preliminary bank layer 300m may be removed by being dry-etched. When the preliminary bank layer 300m is patterned, wet etching may not be used. FIG. 11 shows that a side surface of the bank layer 300 is formed to have an inclined surface tapered in a forward direction. However, the present disclosure is not limited thereto. In an embodiment, the side surface of the bank layer 300 may be formed to be perpendicular to or substantially perpendicular to the substrate 100. In an embodiment, the side surface of the bank layer 300 may be formed to have an inclined surface tapered in a reverse direction.

After the bank layer 300 is formed by patterning the preliminary bank layer 300m, a preliminary sacrificial layer PRm may be formed to fill the first sub-opening OP1 and the second sub-opening OP2 and cover the bank layer 300. In an embodiment, the preliminary sacrificial layer PRm may include a suitable material including a photo-active compound (PAC).

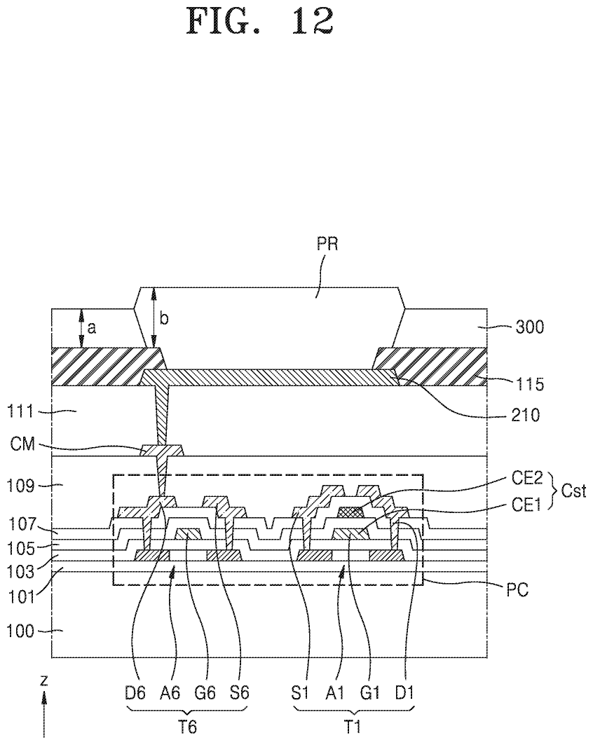

Referring to FIG. 12, a sacrificial layer PR may be formed by patterning the preliminary sacrificial layer PRm. The preliminary sacrificial layer PRm may be patterned, so that a height b from an upper surface of the pixel defining layer 115 to an upper surface of the sacrificial layer PR is formed to be greater than the height a from the upper surface of the pixel defining layer 115 to the upper surface of the bank layer 300. The preliminary sacrificial layer PRm may be patterned through exposure and development processes. In this case, a separate planarization process (e.g., chemical mechanical polishing (CMP)) may not be required.

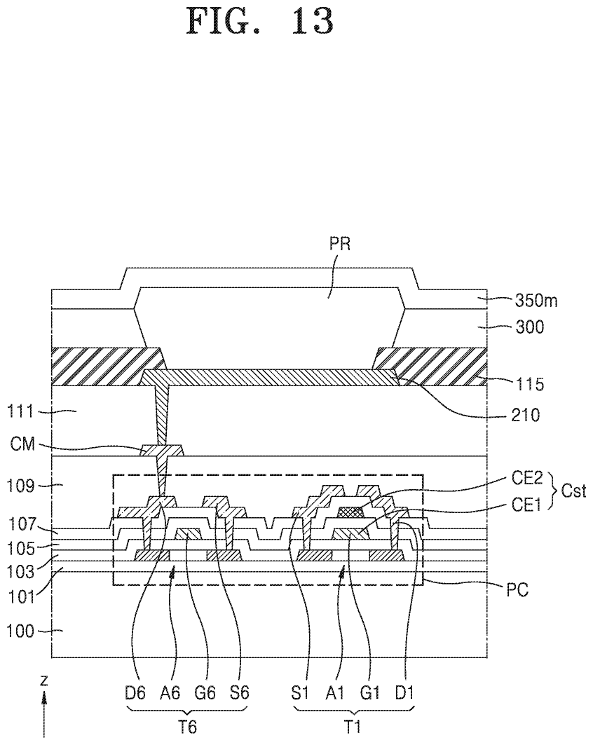

Referring to FIG. 13, a preliminary overhang layer 350m may be formed on the bank layer 300 and the sacrificial layer PR. The overhang layer 350 may be formed to have a single-layer structure or a multi-layered structure, each including a conductive material, an organic insulating material, and/or an inorganic insulating material. In an embodiment, the overhang layer 350 may include Ti.

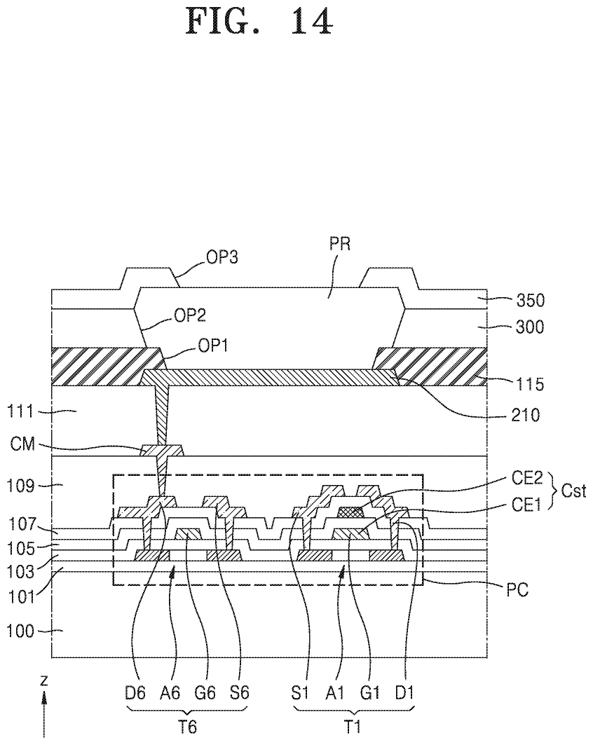

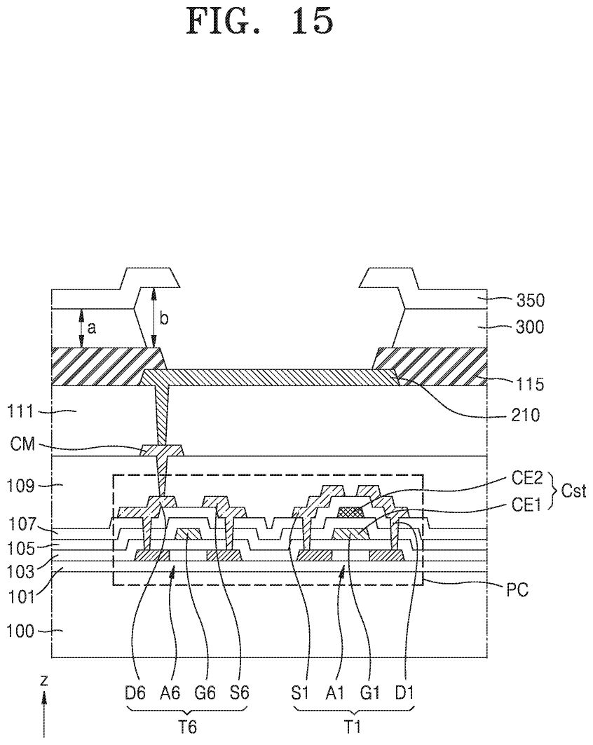

Referring to FIGS. 14 and 15, the overhang layer 350 may be formed to have the third sub-opening OP3 overlapping with the first sub-opening OP1 and the second sub-opening OP2 by removing a portion of the preliminary overhang layer 350m. The overhang layer 350 may be formed so that a width of the third sub-opening OP3 of the overhang layer 350 is less than a width of the second sub-opening OP2 of the bank layer 300. In an embodiment, the preliminary overhang layer 350m may be removed by being dry-etched. Next, the sacrificial layer PR may be removed. In an embodiment, the sacrificial layer PR may be removed by a suitable process, such as ashing or the like. Because the sacrificial layer PR is removed so that the height b from the upper surface of the pixel defining layer 115 to the upper surface of the sacrificial layer PR is greater than the height a from the upper surface of the pixel defining layer 115 to the upper surface of the bank layer 300, the height b from the upper surface of the pixel defining layer 115 to the bottom surface of the tip TP of the overhang layer 350 obtained by being patterned may be greater than the height a from the upper surface of the pixel defining layer 115 to the upper surface of the bank layer 300.

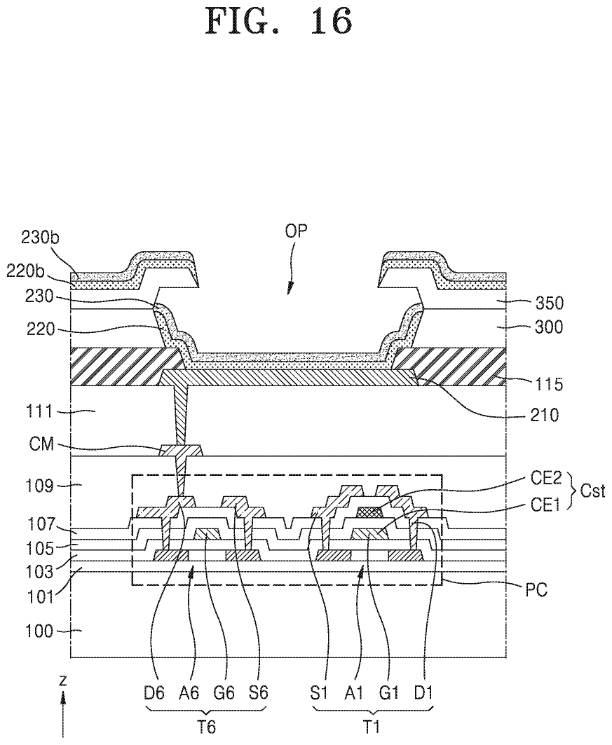

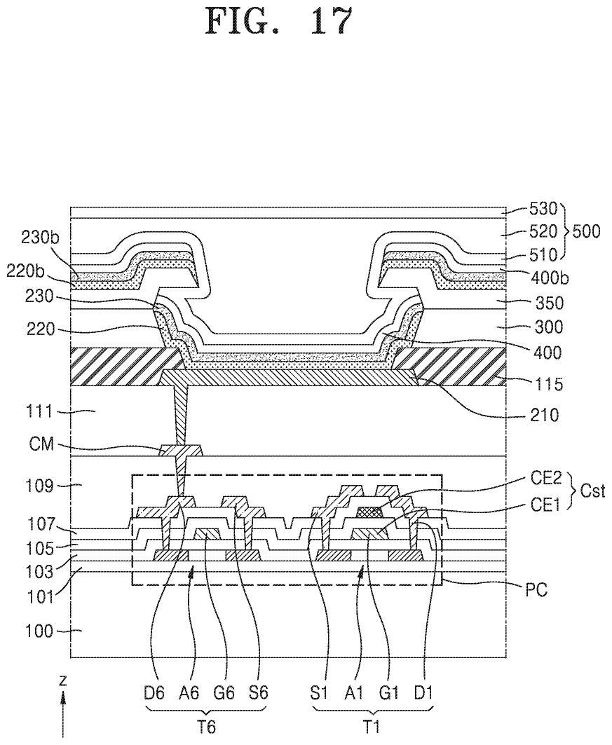

Referring to FIGS. 16 and 17, the intermediate layer 220 may be formed on the pixel electrode 210 through the opening OP, and the opposite electrode 230 may be formed on the intermediate layer 220 through the opening OP. The intermediate layer 220 and the opposite electrode 230 may be formed to overlap with the pixel electrode 210. In an embodiment, the intermediate layer 220 and the opposite electrode 230 may each be formed through a deposition method, such as thermal evaporation. The edge or the outer portion (e.g., the peripheral portion) of the opposite electrode 230 may cover the edge or the outer portion (e.g., the peripheral portion) of the intermediate layer 220. The opposite electrode 230 may be formed to be electrically connected to the bank layer 300. In an embodiment, the opposite electrode 230 may be formed so that the edge or the outer portion (e.g., the peripheral portion) of the opposite electrode 230 covers the edge or the outer portion (e.g., the peripheral portion) of the intermediate layer 220, and is in contact with the side surface of the bank layer 300. The opposite electrode 230 may be formed to be electrically connected to the overhang layer 350. In an embodiment, the edge or the outer portion (e.g., the peripheral portion) of the opposite electrode 230 may be formed to be in contact with the overhang layer 350.

In an embodiment, the intermediate layer 220 and the opposite electrode 230 may be deposited without using a separate mask. Accordingly, a deposition material for forming the intermediate layer 220 and a deposition material for forming the opposite electrode 230 may form the dummy intermediate layer 220b and the dummy opposite electrode 230b on the overhang layer 350. The intermediate layer 220 and the dummy intermediate layer 220b may be formed to be separated and spaced apart from each other, and the opposite electrode 230 and the dummy opposite electrode 230b may be formed to be separated and spaced apart from each other. The intermediate layer 220 and the dummy intermediate layer 220b may include the same material as each other and/or the same number of sub-layers (e.g., a first common layer, an emission layer, and a second common layer) as each other. The opposite electrode 230 and the dummy opposite electrode 230b may include the same material as each other. The intermediate layer 220 and the dummy intermediate layer 220b may be formed by the same process as each other. The opposite electrode 230 and the dummy opposite electrode 230b may be formed by the same process as each other.

The capping layer 400 may be formed on the opposite electrode 230. When the capping layer 400 is formed, the dummy capping layer 400b may also be formed on the dummy opposite electrode 230b. In an embodiment, the dummy capping layer 400b may be disposed between the dummy opposite electrode 230b and the first inorganic encapsulation layer 510 to be described in more detail below. In an embodiment, a process of forming the capping layer 400 may be omitted as needed or desired.

The first inorganic encapsulation layer 510 may be formed to fill the opening OP. The organic encapsulation layer 520 may be formed on the first inorganic encapsulation layer 510. The second inorganic encapsulation layer 530 may be formed on the organic encapsulation layer 520.

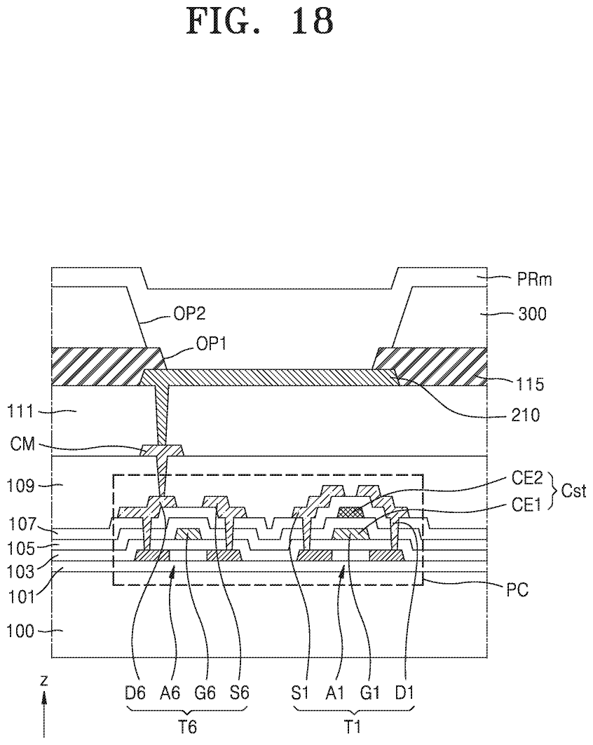

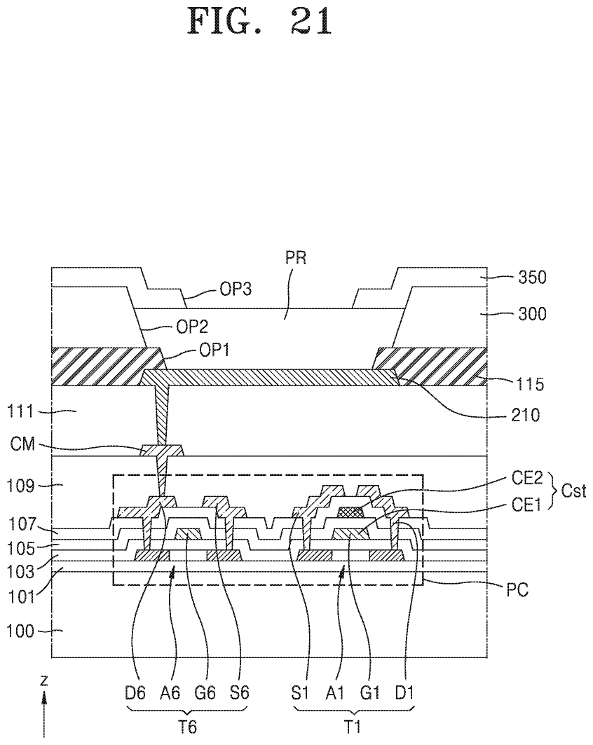

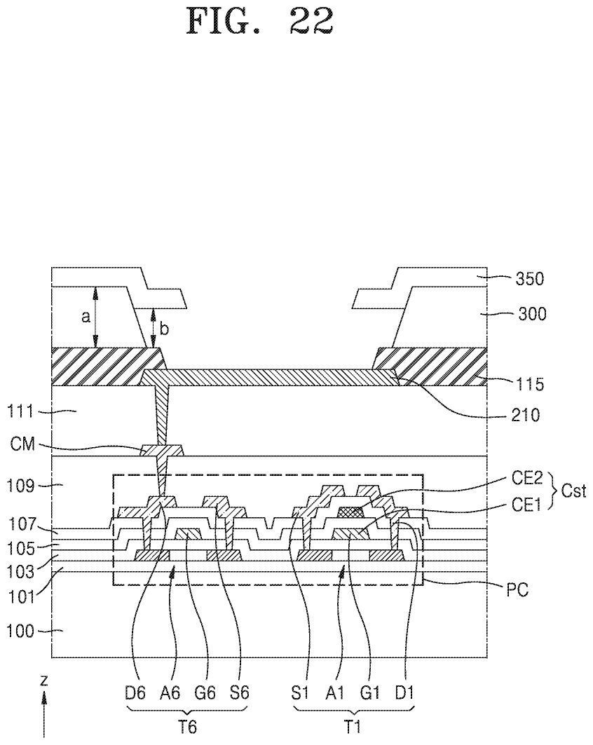

FIGS. 18 through 24 are cross-sectional views sequentially illustrating some processes of a method of manufacturing a display apparatus according to an embodiment.

Referring to FIG. 18, the preliminary sacrificial layer PRm may be formed to fill the first sub-opening OP1 and the second sub-opening OP2, and cover the bank layer 300. Configurations having the same reference numerals as those described above with reference to FIG. 11 may be formed in the same or substantially the same method as those described above with reference to FIG. 11, and thus, redundant description thereof are not repeated.

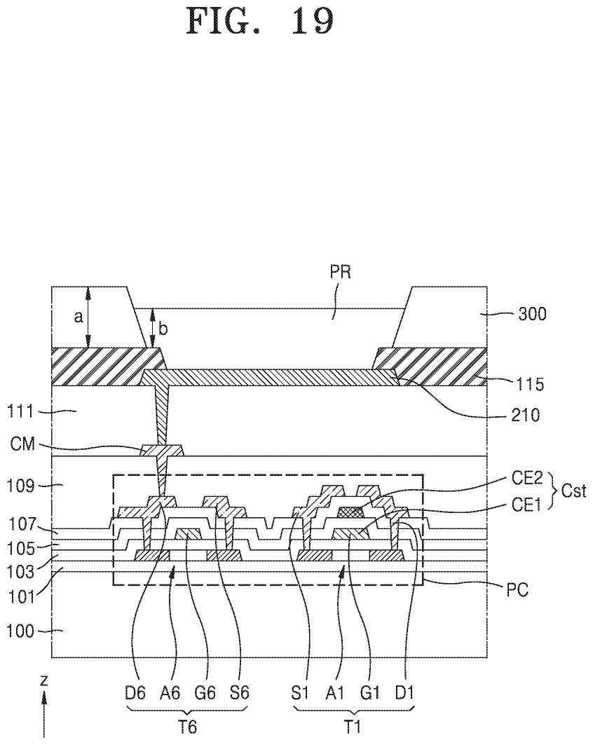

Referring to FIG. 19, the preliminary sacrificial layer PRm may be patterned to form the sacrificial layer PR. The preliminary sacrificial layer PRm may be patterned so that the height b from the upper surface of the pixel defining layer 115 to the upper surface of the sacrificial layer PR is formed to be less than the height a from the upper surface of the pixel defining layer 115 to the upper surface of the bank layer 300.

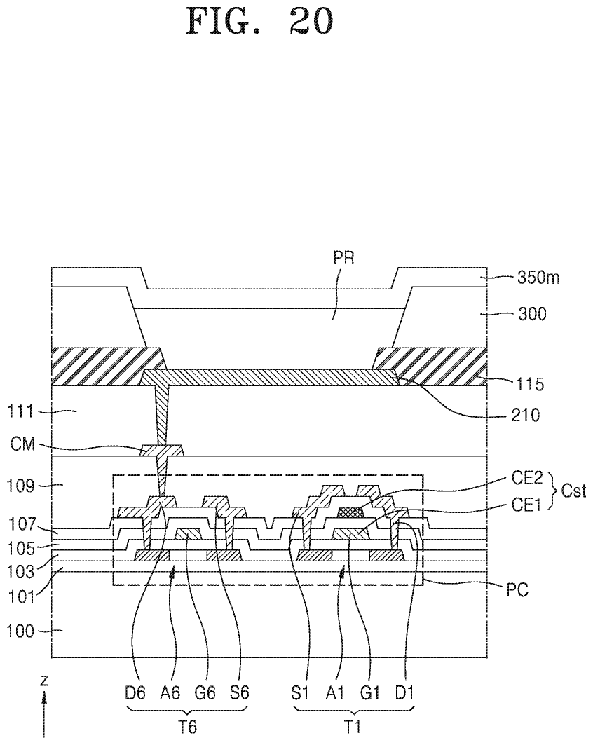

Referring to FIGS. 20 to 22, the preliminary overhang layer 350m may be formed on the bank layer 300 and the sacrificial layer PR. The overhang layer 350 may be formed to have the third sub-opening OP3 overlapping with the first sub-opening OP1 and the second sub-opening OP2 by removing a portion of the preliminary overhang layer 350m. Then, the sacrificial layer PR may be removed. The height b from the upper surface of the pixel defining layer 115 to the bottom surface of the tip TP of the overhang layer 350 obtained by being patterned may be less than the height a from the upper surface of the pixel defining layer 115 to the upper surface of the bank layer 300.

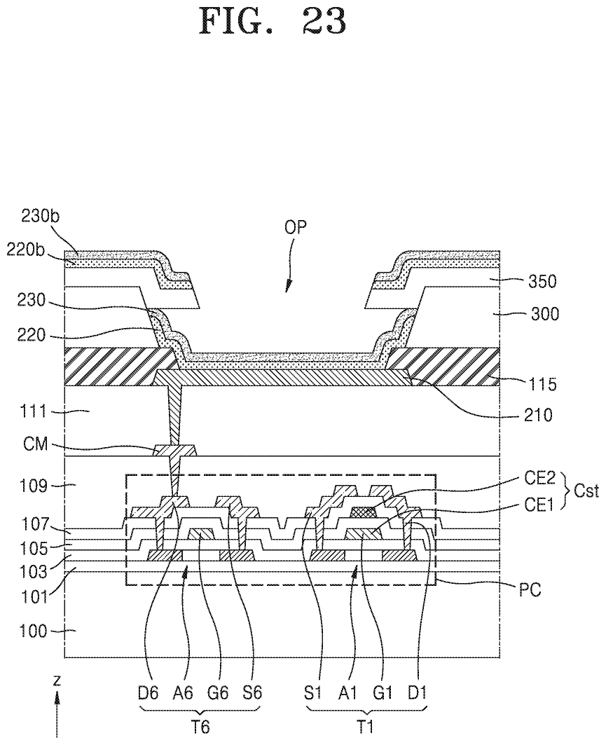

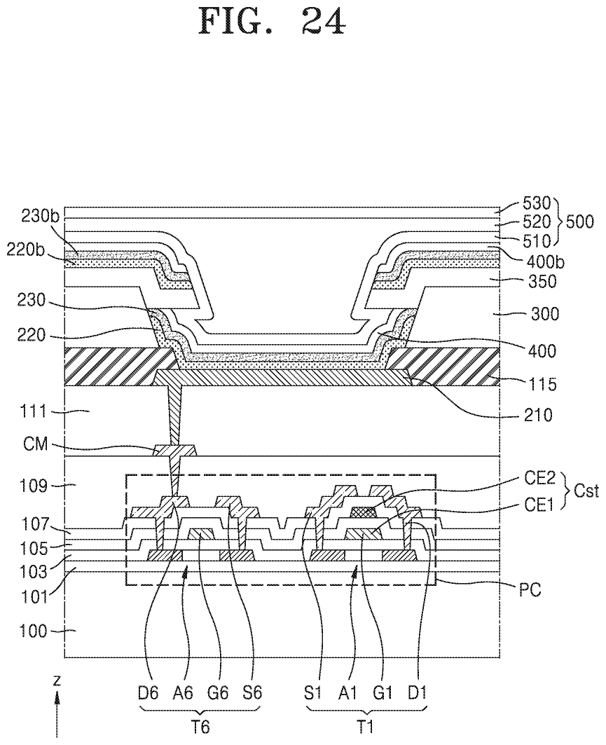

Referring to FIGS. 23 and 24, the intermediate layer 220 may be formed on the pixel electrode 210 through the opening OP, and the opposite electrode 230 may be formed on the intermediate layer 220 through the opening OP.

According to one or more embodiments of the present disclosure described above, a display apparatus having reduced process time, reduced costs, and/or improved light emission efficiency, and a method of manufacturing the same, may be provided. However, the spirit and scope of the present disclosure are not limited to those described above.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display apparatus comprising:
a pixel electrode;
a pixel defining layer on the pixel electrode, and having an opening exposing at least a portion of the pixel electrode;
a bank layer on the pixel defining layer;
an overhang layer on the bank layer;
an intermediate layer on the pixel electrode; and
an opposite electrode on the intermediate layer,
wherein the overhang layer comprises a tip protruding toward the pixel electrode from a point where a bottom surface of the overhang layer and a side surface of the bank layer facing toward the pixel electrode meet each other, and
wherein a height from an upper surface of the pixel defining layer to an upper surface of the bank layer is different from a height from the upper surface of the pixel defining layer to a bottom surface of the tip of the overhang layer.

2. The display apparatus of claim 1, wherein:
the tip of the overhang layer has an opening overlapping with the pixel electrode;
the bank layer has an opening overlapping with the pixel electrode; and
a width of the opening of the tip is less than a width of the opening of the bank layer.

3. The display apparatus of claim 1, wherein the height from the upper surface of the pixel defining layer to the bottom surface of the tip of the overhang layer is greater than the height from the upper surface of the pixel defining layer to the upper surface of the bank layer.

4. The display apparatus of claim 3, wherein the opposite electrode is electrically connected to the bank layer.

5. The display apparatus of claim 3, wherein the opposite electrode is electrically connected to the overhang layer.

6. The display apparatus of claim 5, wherein the overhang layer comprises a conductive material.

7. The display apparatus of claim 1, wherein the height from the upper surface of the pixel defining layer to the bottom surface of the tip of the overhang layer is less than the height from the upper surface of the pixel defining layer to the upper surface of the bank layer.

8. The display apparatus of claim 7, wherein the opposite electrode is electrically connected to the bank layer.

9. The display apparatus of claim 8, wherein the overhang layer comprises an organic insulating material or an inorganic insulating material.

10. The display apparatus of claim 7, wherein the opposite electrode is electrically connected to the overhang layer.

11. The display apparatus of claim 10, wherein the overhang layer comprises a conductive material.

12. The display apparatus of claim 1, further comprising:
an encapsulation layer on the overhang layer and the opposite electrode;
a dummy intermediate layer on the overhang layer; and
a dummy opposite electrode on the dummy intermediate layer,
wherein:
the dummy intermediate layer and the dummy opposite electrode are located between the overhang layer and the encapsulation layer;
the dummy intermediate layer comprises the same material as a material of the intermediate layer; and
the dummy opposite electrode comprises the same material as a material of the opposite electrode.

13. A method of manufacturing a display apparatus, the method comprising:
forming a pixel electrode on a substrate;
forming a pixel defining layer having an opening exposing at least a portion of the pixel electrode;
forming a preliminary bank layer on the pixel defining layer and the pixel electrode;
forming a bank layer having an opening overlapping with the opening of the pixel defining layer by patterning the preliminary bank layer;
forming a preliminary sacrificial layer to fill the opening of the pixel defining layer and the opening of the bank layer, and to cover the bank layer;
forming a sacrificial layer by patterning the preliminary sacrificial layer;
forming a preliminary overhang layer on the bank layer and the sacrificial layer;
forming an overhang layer having an opening overlapping with the opening of the pixel defining layer and the opening of the bank layer by patterning the preliminary overhang layer; and
removing the sacrificial layer,
wherein the forming of the overhang layer comprises removing a portion of the overhang layer so that a width of the opening of the overhang layer is less than a width of the opening of the bank layer.

14. The method of claim 13, wherein the preliminary sacrificial layer is formed with a material comprising a photo-active compound.

15. The method of claim 13, wherein the forming of the sacrificial layer comprises removing the preliminary sacrificial layer so that a height from an upper surface of the pixel defining layer to an upper surface of the sacrificial layer is greater than a height from the upper surface of the pixel defining layer to an upper surface of the bank layer.

16. The method of claim 15, further comprising:
forming an intermediate layer on the pixel electrode; and
forming an opposite electrode on the intermediate layer,
wherein the opposite electrode is formed to be electrically connected to the overhang layer.

17. The method of claim 13, wherein the forming of the sacrificial layer comprises removing the preliminary sacrificial layer so that a height from an upper surface of the pixel defining layer to an upper surface of the sacrificial layer is less than a height from the upper surface of the pixel defining layer to an upper surface of the bank layer.

18. The method of claim 17, further comprising:
forming an intermediate layer on the pixel electrode; and
forming an opposite electrode on the intermediate layer,
wherein the opposite electrode is formed to be electrically connected to the bank layer.

19. The method of claim 18, wherein the opposite electrode is formed to be electrically connected to the overhang layer.

20. The method of claim 13, wherein the forming of the bank layer comprises removing the preliminary bank layer by dry-etching.
